(19) United States
(12) Patent Application Publication
(10) Pub. No.: US 2026/0079215 A1
(43) Pub. Date: Mar. 19, 2026

(54) Method for Controlling Battery Module of Rechargeable Battery

(71) Applicant: TOYOTA BATTERY Co., Ltd., Shizuoka (JP)

(72) Inventor: Soichiro Fukamachi, Toyohashi-shi (JP)

(21) Appl. No.: 19/058,461

(22) Filed: Feb. 20, 2025

(30) Foreign Application Priority Data
Sep. 17, 2024 (JP) 2024-160423

(51) Int. Cl. G01R 31/396; G01R 31/367; G01R 31/378; G01R 31/382; G01R 31/392

(52) U.S. Cl. CPC G01R 31/396; G01R 31/367; G01R 31/378; G01R 31/382; G01R 31/392

(57) ABSTRACT

A method, executed by a control device, for controlling a battery module having battery cells includes: estimating an ion concentration rate of each battery cell; plotting the estimated ion concentration rate on a common axis, any battery cell serving as a reference battery cell, and a remaining battery cell serving as a non-reference battery cell; adjusting a length of the non-reference battery cell in accordance with the reference battery cell; shifting a position of the ion concentration rate of the non-reference battery cell on the axis to agree with that of the reference battery cell; and estimating an SOC of the battery module using a range between the ion concentration rate at a lowest upper limit voltage of the battery cells and the ion concentration rate at a highest lower limit voltage of the battery cells as an SOC range of 100% to 0% of the battery module.

### CROSS-REFERENCE TO RELATED APPLICATIONS

This application is based upon and claims the benefit of priority from Japanese Patent Application No. 2024-160423, filed on Sep. 17, 2024, the entire contents of which are incorporated herein by reference.

### BACKGROUND

### 1. Field

The following description relates to a method for controlling a battery module of rechargeable batteries. More specifically, the following description relates to a method for controlling a battery module of rechargeable batteries in which battery cells forming the battery module vary in state of charge (SOC).

### 2. Description of Related Art

Battery electric vehicles (BEV) or hybrid electric vehicles (HV) are powered by rechargeable batteries, for example, lithium-ion rechargeable batteries having suitable battery capacities and input-output characteristics. Since those lithium-ion rechargeable batteries for driving vehicles require high voltages and high currents, multiple battery cells are stacked into a battery module and used in a battery pack of combined battery modules. Such lithium-ion rechargeable batteries are controlled based on the SOC (%). Accordingly, it is desirable that the battery module of the lithium-ion rechargeable batteries is also appropriately charged and discharged in accordance with an accurate SOC.

Although the SOC of a single battery cell is simple, the SOC of a battery module has no fixed definition and is defined and estimated in various manners.

Japanese Laid-Open Patent Publication No. 2017-198455 discloses an example of a state of charge estimation device including a charge controller and an estimation unit. When at least one of batteries included in a battery module satisfies a full-charge determination condition, the charge controller stops charging of the battery module. The estimation unit sets the SOC (%) of the fully-charged battery, which satisfied the full-charge determination condition, to 100%. Further, the estimation unit estimates the SOC (%) of an under-charged battery, that is not the fully-charged battery, from the voltage of the under-charged battery when the charging of the battery module was stopped. This allows for estimation of the SOC (%) of each battery even when the multiple batteries included in the battery module vary in charged state or voltage.

Japanese Laid-Open Patent Publication No. 2021-039063 describes an information aggregation device that obtains, from a battery ECU arranged in each cell unit, information related to the SOC (%) of the cell unit, a terminal-to-terminal voltage of each battery cell forming the cell unit, and a charging/discharging current of the cell unit. When the terminal-to-terminal voltage of each battery cell is within a range specified by an upper limit value and a lower limit value, the information aggregation device estimates the SOC (%) of a battery module through selective control. This improves the accuracy of estimating the SOC (%) of the battery module.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Multiple rechargeable batteries forming a single battery module may be in different deterioration states. If a battery module including rechargeable batteries in different deterioration states is controlled solely based on the voltage of the battery module or the voltages of the battery cells forming the battery module, a relatively large load may be applied to some of the battery cells or the capacity of the battery cells may not be used sufficiently.

Accordingly, the SOC of the battery module may change differently in response to the same input-output current depending on its SOC level. Moreover, the SOC of the battery module is typically corrected when the voltage reaches an upper limit or a lower limit. Thus, it is difficult to predict when the battery module becomes fully charged or fully discharged.

Japanese Laid-Open Patent Publication No. 2024-054481 discloses a method for calculating a deterioration level of a rechargeable battery suggested by the inventor of the present disclosure. This analysis technique allows for estimation of the capacity of a rechargeable battery even if there is no battery of the same type that is less deteriorated.

Japanese Laid-Open Patent Publication No. 2023-085617 discloses a method for estimating a deterioration level suggested by the inventor of the present disclosure. In this method, a deterioration level estimation device includes a side reaction current calculator and a deterioration index calculator. The side reaction current calculator uses the temperature of a rechargeable battery to calculate a side reaction current occurring in the anode of the rechargeable battery. The deterioration index calculator calculates a deterioration index of the rechargeable battery based on the side reaction current calculated by the side reaction current calculator. This method reduces the processing load by estimation of the deterioration level of the rechargeable battery without limiting the time when the estimation may be performed.

Japanese Laid-Open Patent Publication No. 2022-139508 discloses an estimation method suggested by the inventor of the present disclosure. In this method, an estimation device calculates a solid-phase potential difference and a liquid-phase potential difference of a rechargeable battery, and calculates a voltage error ΔV between a measured voltage value of the rechargeable battery and the solid-phase potential difference and the liquid-phase potential difference of the rechargeable battery. Then, the estimation device calculates a salt concentration dependent parameter that minimizes a sum of a reaction overvoltage and a DC resistance voltage of the rechargeable battery, which is equivalent to the voltage error ΔV. The estimation device identifies the salt concentration that corresponds to the calculated salt concentration dependent parameter based on a corresponding relationship between the salt concentration dependent parameter and the salt concentration. The estimation device calculates a difference between the identified salt concentration and an initial value of the salt concentration of the rechargeable battery. This method improves the accuracy of estimating the salt concentration of the rechargeable battery.

The inventor suggests the present disclosure based on the above-described suggestions.

In one general aspect, a method for controlling a battery module in which battery cells of a rechargeable battery are combined is provided. The method includes; estimating, by a control device, an ion concentration rate θ of an active material in an electrode plate of each battery cell; plotting, by the control device, the estimated ion concentration rate θ of the each battery cell on a common θ-axis, any one of the battery cells serving as a reference battery cell, and a remaining one of the battery cells serving as a non-reference battery cell; adjusting, by the control device, a length of the non-reference battery cell in accordance with a capacity of the non-reference battery cell based on a length of the reference battery cell that serves as a battery cell having a reference length value of 1; shifting, by the control device, a position of the ion concentration rate θ of the non-reference battery cell on the θ-axis to agree with a position of the ion concentration rate θ of the reference battery cell on the θ-axis; and estimating, by the control device, an SOC of the battery module using a range between the ion concentration rate θ at a lowest upper limit voltage of the battery cells and the ion concentration rate θ at a highest lower limit voltage of the battery cells as an SOC range of 100% to 0% of the battery module.

With the above method, the estimating the ion concentration rate θ of the active material may include calculating a cathode solid-phase potential difference and an anode solid potential difference in a thickness-wise direction of the each battery cell using a solid-phase diffusion model of the rechargeable battery, expressing a difference between an average ion concentration of the active material and an ion concentration of an active material surface by a first-order lag model, obtaining the ion concentration of the active material surface from the average ion concentration of the active material and an ion concentration flux of an average volume of the active material, and estimating the ion concentration rate θ from the average ion concentration of the active material surface and a solid-phase maximum ion concentration.

The above method may further include: before the estimating the ion concentration rate θ of the active material, estimating, by the control device, a capacity of the electrode plate of the each battery cell; and before the estimating the ion concentration rate θ of the active material, estimating, by the control device, a deterioration level of the each battery cell.

The above method may further include, after the estimating the SOC of the battery module, estimating, by the control device, the SOC based on only the ion concentration rate θ of the reference battery cell.

The above method may further include, after the estimating the SOC of the battery module, determining, by the control device, any of the battery cells to be anomalous if the any of the battery cells has a greater amount of change in the SOC, which is estimated based on the ion concentration rate θ, than other ones of the battery cells.

The above method may further include, before the estimating the SOC of the battery module, adjusting, by the control device, voltage of the battery cells by charging one of the battery cells having the lowest upper limit voltage or discharging one of the battery cells having the highest lower limit voltage.

With the above method, the estimating the capacity of the electrode plate of the each battery cell may include: executing, by a computer processor, an actual value acquisition process that generates an actual value SOC-voltage curve using a measurement result of an open-circuit voltage in the SOC range of 0% to 100% of the each battery cell; executing, by the computer processor, a theoretical value generation process that generates, using a fitting function, a theoretical value SOC-voltage curve calculated from a difference between a cathode open-circuit potential theoretical curve, which is computed from a content of at least one component in a cathode composite of the each battery cell, and an anode open-circuit potential theoretical curve, which is computed from on a content of at least one component in an anode composite of the each battery cell; executing, by the computer processor, an evaluation value calculation process that calculates an evaluation value using an evaluation function for calculating the evaluation value indicating a difference between the theoretical value SOC-voltage curve and the actual value SOC-voltage curve; and executing, by the computer processor, an analysis process that repeatedly executes the theoretical value generation process and the evaluation value calculation process while changing a shift amount parameter, which is used in the fitting function to shift at least one of the cathode open-circuit potential theoretical curve and the anode open-circuit potential theoretical curve in an SOC direction, and a scaling rate parameter, which is used in the fitting function to adjust a length of at least one of the cathode open-circuit potential theoretical curve and the anode open-circuit potential theoretical curve in the SOC direction, and then outputs the shift amount parameter that minimizes the evaluation value as the deterioration level of the each battery cell.

With the above method, the estimating the deterioration level of the each battery cell may include calculating a side reaction current occurring in an anode of the each battery cell using a temperature of the each battery cell, and calculating a deterioration index of the each battery cell based on the calculated side reaction current.

With the above method, the electrode plate may include a cathode.

With the above method, the rechargeable battery may include a lithium-ion rechargeable battery. With the above method, the length may be a length of a line segment connecting the ion concentration ratio θ at the lowest upper limit voltage and the ion concentration ratio θ at the highest lower limit voltage plotted on the common θ-axis.

Other features and aspects will be apparent from the following detailed description, the drawings, and the claims.

### BRIEF DESCRIPTION OF THE DRAWINGS

FIG. 1 is a block diagram showing the configuration of a control device in accordance with an embodiment.

FIG. 2 is a flowchart illustrating the procedure of a method for controlling a battery module of lithium-ion rechargeable batteries in accordance with the embodiment.

FIG. 3 is a graph illustrating the procedure of cathode capacity estimation, with an upper graph section showing an SOC-OCV curve (state of charge-voltage curve) obtained through measurements and a lower graph section showing open-circuit potential (OCP) curves of a cathode and an anode.

FIG. 4 is a flowchart illustrating an example of the process executed by the control device in accordance with a deterioration level estimation program.

FIG. 5 is a diagram illustrating a displacement between corresponding points of the cathode and the anode caused by a change in an ion concentration of a solid-phase surface of the anode due to occurrence of a side reaction current, and a concept of correcting the displacement.

FIG. 6 is a diagram showing a corrected lower limit lithium-ion concentration rate θₚ and a corrected upper limit lithium-ion concentration rate θₚ.

FIG. 7 is a diagram showing a cathode ion concentration rate θₚ plotted as a θ coordinate.

FIG. 8 is a diagram illustrating battery capacity correction performed on the cathode ion concentration rate θₚ plotted as a θ coordinate.

FIG. 9 is a diagram illustrating position adjustment of each battery cell in accordance with the cathode ion concentration rate θₚ of a reference battery cell CBS.

FIG. 10 is a diagram illustrating a battery cell voltage adjustment step (S7).

FIG. 11 is a diagram illustrating a battery module SOC estimation step (S8).

FIG. 12 is a diagram illustrating a simplified SOC estimation step (S9).

FIG. 13 is a diagram illustrating an anomalous battery cell determination step (S11).

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### Overview of the Present Embodiment

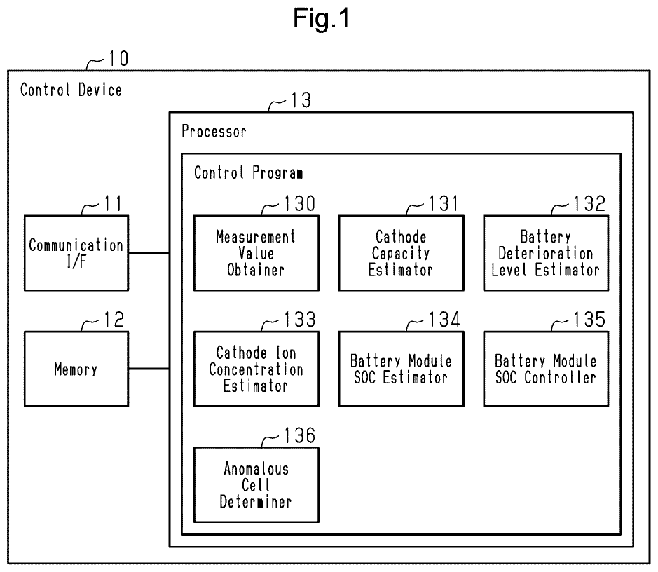

A method for controlling a battery module in accordance with the present disclosure will now be described with reference to FIGS. 1 to 13. The present disclosure will be described using an embodiment of a method for controlling a battery module of lithium-ion rechargeable batteries executed by a control device 10. The embodiment is not intended to limit the present disclosure.

As described in Background section, there is no unified method for evaluating the SOC (%) of a battery module, and thus estimation results obtained by different methods may vary. Accordingly, the inventor of the present disclosure focused on an ion concentration rate θ of the active material in an electrode plate that may be physically estimated at a relatively high degree of accuracy.

### Ion Concentration Rate θ

When characteristics of battery cells CB forming a battery module vary due to deterioration or the like, it is difficult to estimate an accurate SOC (%) of the battery module even if an open-circuit voltage OCV (V) of the entire battery module is measured. Further, when the battery cells CB forming the battery module vary in deterioration level, an accurate SOC (%) of each battery cell CB cannot be estimated by measuring an open-circuit voltage OCV (V) of each battery cell CB.

Accordingly, in order to estimate an accurate SOC (%) of each battery cell CB, the ion concentration rate θ is used.

The active material in a rechargeable battery refers to a substance that performs storing and releasing of ions in the cathode or the anode. When charging is performed, ions are released from the cathode active material and stored in the anode active material through an electrolyte solution. When discharging is performed, ions are released from the anode active material and stored in the cathode active material through the non-aqueous electrolyte solution.

### Cathode Lithium-Ion Concentration Rate θₚ of the Present Embodiment

In the present embodiment, the present disclosure is described using an example in which a rechargeable battery is a lithium-ion rechargeable battery, ions are lithium ions Li⁺, and an ion concentration is a cathode lithium-ion concentration (mol/m³). The present embodiment is not intended to limit the rechargeable battery of the present disclosure to a lithium-ion rechargeable battery or the ions to lithium ions Li⁺.

The active material stores ions. The ion concentration of the active material is represented by “c” (mol/cm³). The lithium-ion concentration of the surface of the active material is represented by “cₛ” (mol/cm³). The subscript “s” represents the surface of the active material. An average ion concentration of the active material is represented by “c_{avg}” (mol/cm³). The subscript “avg” represents average. The average value is obtained by calculating an arithmetic mean of measurement values. Accordingly, the average ion concentration of the surface of the active material is represented by “c_{s, avg}” (mol/cm³). In the present embodiment, the average ion concentration of the surface of the active material in the cathode of the lithium-ion rechargeable battery is expressed by “c_{s, p, avg}” (mol/cm³). The subscript “p” represents the cathode. For the anode, the subscript “n” is used.

The type of the active material determines a solid-phase maximum ion concentration “c_{s, max}” (mol/cm³) of metal ions that can be stored in the active material. In the present embodiment, the solid-phase maximum ion concentration of the cathode of the lithium-ion rechargeable battery is represented by “c_{s, p, max}” (mol/cm³).

The cathode active material in the lithium-ion rechargeable battery of the present embodiment is, for example, a material capable of storing and releasing lithium ions Li⁺. Specifically, the cathode active material contains a lithium transition metal oxide having, for example, a layered crystal structure. In addition to Li, the lithium transition metal oxide contains one or more predetermined transition metal elements. Preferably, the transition metal element contained in the lithium transition metal oxide is at least one of Ni, Co, and Mn. Examples of the lithium transition metal oxide include lithium cobalt oxide (LiCoO₂), lithium manganese oxide (LiMn₂O₄), lithium nickel oxide (LiNiO₂), or the like. Furthermore, the cathode active material of the present embodiment may be of a ternary type, referred to as NCM, which has a lithium transition metal oxide containing all of Ni, Co, and Mn.

### Ion Concentration Rate θ and Active Material SOC

The inventor of the present disclosure estimates the cathode ion concentration rate θₚ (%) of each battery cell CB from the average ion concentration c_{s, p, avg} (mol/cm³) of the surface of the cathode active material and the solid-phase maximum ion concentration c_{s, p, max} (mol/cm³) of the cathode. The inventor has found that these values allow for estimation of an accurate SOC (%) of the cathode.

### Method for Controlling Battery Module of the Present Embodiment

The inventor of the present disclosure uses the above-described finding to estimate an accurate active material SOC (%) of each battery cell CB. In this case, the active material SOC (%) is defined using a physical quantity. This improves the accuracy of estimating the active material SOC (%) of the electrode plates included in the battery module. On such a premise, the battery module can be controlled so that the battery module SOC (%) changes in the same manner regardless of whether the battery module SOC (%) is in a relatively high region or a relatively low region, without applying an excessive load to the battery cells CB through over-charging or over-discharging. This allows for prediction of when the battery module becomes fully charged or fully discharged. Therefore, the battery module is effectively controlled within its performance range without applying an excessive load to the battery cells CB. The related configurations and the procedure of the method for controlling the battery module in accordance with the present embodiment will now be described in detail.

### Configuration of the Present Embodiment

FIG. 1 is a block diagram showing the configuration of the control device 10 in accordance with the present embodiment. The control device 10 is configured to estimate the SOC (%) of a battery module of lithium-ion rechargeable batteries installed in a vehicle. A specific example of the control device 10 includes an electronic control unit (ECU) or the like installed in the vehicle.

The control device 10 includes a communication interface (I/F) 11, memory 12, and a processor 13. The communication I/F 11 is an interface that transmits and receives signals between the control device 10 and another device or a battery pack of lithium-ion rechargeable batteries installed in the vehicle.

The memory 12 may be of any type, such as a read-only memory (ROM), a solid state drive (SSD), or the like. The memory 12 stores control programs executed by the processor 13 or data that is prepared in advance. Also, the memory 12 includes a random-access memory (RAM) that temporarily stores various types of information processed by the processor 13.

The processor 13 is a computer, such as a central processing unit (CPU), a micro-processing unit (MPU), or the like. The processor 13 executes a control program stored in the memory 12 to perform a control method specified by the control program.

The control program includes a measurement value obtainer 130, a cathode capacity estimator 131, a battery deterioration level estimator 132, a cathode ion concentration estimator 133, a battery module SOC estimator 134, a battery module SOC controller 135, and an anomalous cell determiner 136. These program modules may be executed by an integrated circuit, such as a field-programmable gate array (FPGA), an application-specific integrated circuit (ASIC), or the like.

The measurement value obtainer 130 is a program module that obtains a measurement value of a lithium-ion rechargeable battery, such as a measurement current value, a measurement voltage value, or a measurement temperature. The measurement value obtainer 130 obtains the measurement current value of the lithium-ion rechargeable battery through the communication I/F 11 from a current sensor (not shown) that detects a current of the lithium-ion rechargeable battery. Also, the measurement value obtainer 130 obtains the measurement voltage value of the lithium-ion rechargeable battery through the communication I/F 11 from a voltage sensor (not shown) that detects a voltage of the lithium-ion rechargeable battery. Furthermore, the measurement value obtainer 130 obtains the measurement temperature of the lithium-ion rechargeable battery through the communication I/F 11 from a temperature sensor (not shown) that detects a temperature T (K) of the lithium-ion rechargeable battery.

The cathode capacity estimator 131 estimates the capacity of the cathode of each battery cell CB.

The battery deterioration level estimator 132 estimates a deterioration level of each battery cell CB.

The cathode ion concentration estimator 133 estimates the cathode ion concentration rate θₚ (%) of each battery cell CB.

The battery module SOC estimator 134 estimates the SOC (%) of the battery module using a range between the cathode ion concentration rate θₚ at a lowest upper limit voltage of the multiple battery cells CB and the cathode ion concentration rate θₚ at a highest lower limit voltage of the multiple battery cells CB as an SOC (%) range of 100% to 0% of the battery module.

The battery module SOC estimator 134 estimates the SOC (%) of the battery module in the following steps. First, the battery module SOC estimator 134 plots an estimated cathode ion concentration rate θₚ of each battery cell CB on a common θ-axis, and designates any one of the battery cells CB as a reference battery cell CBS. The remaining batter cells CB each serve as a non-reference battery cell CB. Then, the battery module SOC estimator 134 adjusts the length of each non-reference battery cell CB in accordance with the capacity of the each non-reference battery cell estimated in a capacity estimation step based on the length of the reference battery cell CBS that serves as a battery cell having a reference length value of 1. In an example, the length may be a length of a line segment (a bar described later) connecting the cathode ion concentration rate θₚ at the lowest upper limit voltage and the cathode ion concentration rate θₚ at the highest lower limit voltage plotted on the common θ-axis.

Subsequently, the battery module SOC estimator 134 shifts the position of the cathode ion concentration rate θₚ of each non-reference battery cell CB to agree with the position of the cathode ion concentration rate θₚ of the reference battery cell CBS on the θ-axis. The following procedure is then performed with the battery cells CB on the θ-axis. The battery module SOC estimator 134 estimates the SOC (%) of the battery module using a range between the cathode ion concentration rate θₚ at the lowest upper limit voltage of the battery cells CB and the cathode ion concentration rate θₚ at the highest lower limit voltage of the battery cells CB as the SOC range of 100% to 0% of the battery module.

The battery module SOC controller 135 controls the battery module in the SOC range of 0% to 100% based on the obtained SOC (%) of the battery module.

The anomalous cell determiner 136 determines any of the battery cells CB to be anomalous if the battery cell CB has a greater amount of change in the SOC (%), which is estimated based on the cathode ion concentration rate θₚ, than the other battery cells CB due to self-discharging or the like.

### Procedure of the Present Embodiment

The control device 10 initiates the method for controlling a battery module of lithium-ion rechargeable batteries in accordance with the present embodiment, for example, when operation of a vehicle including the battery module is started. First, a cathode capacity estimation step (S1), a battery deterioration level estimation step (S2), and a cathode ion concentration rate θₚ estimation step (S3) are performed in this order.

Next, the control device 10 plots battery cells CB1 to CB3 on the θ-axis (S4), corrects the battery capacity (Ah) (S5), and adjusts the length of the graphical representation (bar) in accordance with the battery capacity. Then, the control device 10 adjusts the position of each battery cell CB on the θ-axis in accordance with the corresponding cathode ion concentration rate θₚ with reference to the reference battery cell CBS (S6). If necessary, a battery cell voltage adjustment step (S7) may be performed before a battery module SOC estimation step (S8). When this optional step is performed, the control device 10 charges the battery cell CB having the lowest upper limit voltage and discharges the battery cell CB having the highest lower limit voltage. The control device 10 may perform one of or both of the charging and discharging. Then, the control device 10 estimates the SOC (%) of the battery module (S8). In this description, the control device 10 calculates the cathode SOC (%) based on the cathode ion concentration rate θₚ, obtains the SOC (%) of each battery cell CB, and estimates the SOC (%) of the entire battery module. Consequently, the vehicle controls charging and discharging of the battery module based on the estimated SOC (%) of the battery module.

In the present embodiment, a simplified SOC estimation step (S9) is performed using the cathode ion concentration rate θₚ as a fixed value under an assumption that the cathode ion concentration rate θₚ does not change abruptly in a relatively short time. This optional step may reduce the amount of data processing in the vehicle. When a predetermined time elapses (S10: YES), the control device 10 performs an anomalous battery cell determination step (S11). The anomalous battery cell determination step (S11) is optional and may be performed at any time. The method for controlling the battery module in accordance with the present embodiment is ended, for example, when the operation of the vehicle is ended (S12: YES).

Each step will now be described in detail.

### Cathode Capacity Estimation (S1)

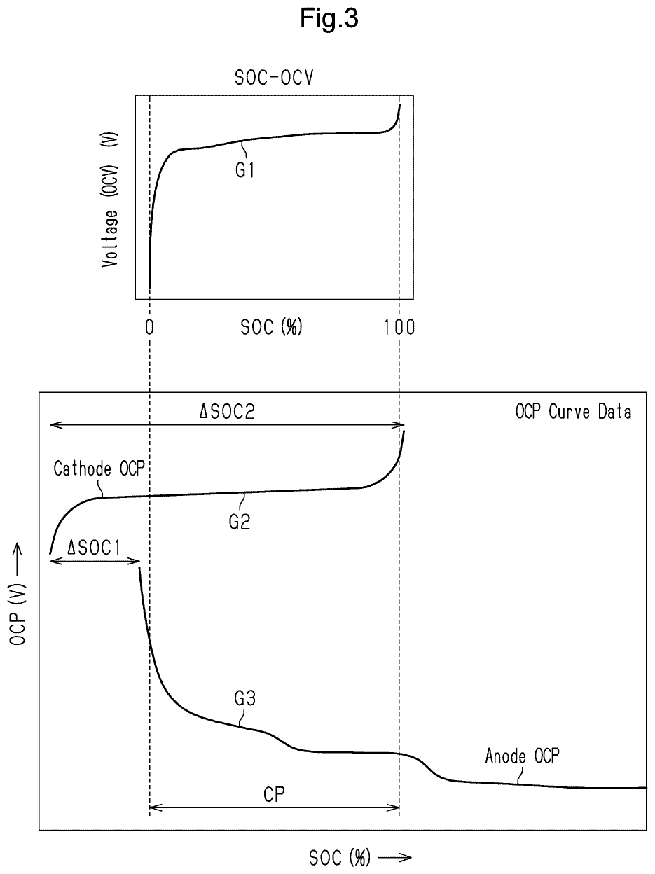

The present procedure corresponds to an example of a capacity estimation step in accordance with the present disclosure. However, there is no limitation to such a configuration. FIG. 3 is a graph illustrating the procedure of the cathode capacity estimation step. The upper graph section of FIG. 3 shows an SOC-OCV curve (state of charge-voltage curve) obtained through measurements. The horizontal axis indicates the SOC (%), and the vertical axis indicates the open-circuit voltage (OCV) (V) corresponding to the SOC (%). The lower graph section of FIG. 3 shows open-circuit potential (OCP) curves of a cathode and an anode. The horizontal axis corresponds to the SOC (%) on the horizontal axis of the upper graph section. The vertical axis indicates the potential (V) of the cathode and the anode.

As shown in the upper graph section of FIG. 3, the OCV (V) of a rechargeable battery changes in accordance with the SOC (%). This is because the cathode potential (V) and the anode potential (V) are changed by charging and discharging, as shown in the lower graph section of FIG. 3. In the lithium-ion rechargeable battery, a difference between the cathode potential (V) and the anode potential (V) corresponds to the OCV (V) between a cathode terminal and an anode terminal. Accordingly, the cathode potential (V) may be measured as the cathode OCP (V), and the anode potential (V) may be measured as the anode OCP (V). Alternatively, the cathode OCP (V) and the anode OCP (V) may be logically obtained from the active material contained in the composites applied to the electrode plates.

As shown in the lower graph section of FIG. 3, the cathode OCP (V) extends to a region in which the SOC of the battery cell CB is less than or equal to 0%. This indicates a state in which there is no lithium that can be released from the anode when the SOC of the battery cell CB is 0% and the cathode can receive lithium even when the SOC reaches 0%.

In the lower graph section of FIG. 3, the anode OCP extends to a region in which the SOC is greater than or equal to 100%. This indicates a state in which there is no lithium that can be released from the cathode when the SOC of the battery cell CB is 100% and the anode can receive lithium even when the SOC (%) reaches 100%. Although details will be described later, as the lithium-ion rechargeable battery deteriorates, the cathode OCP (V) deforms to shift toward the side where the SOC (%) decreases, and the anode OCP (V) deforms to extend toward the side where the SOC (%) increases.

In the cathode capacity estimation step (S1), first, an actual value acquisition process is performed. The actual value acquisition process generates graph G1 of an actual value SOC-voltage curve, such as that shown in the upper graph section of FIG. 3, using a measurement result of the OCV (V) in the SOC (%) range of 0% to 100% of the lithium-ion rechargeable battery.

Subsequently, fitting is performed. In the fitting, first, a theoretical value generation process is performed. The theoretical value generation process generates a theoretical value SOC-voltage curve that is calculated from a difference between curve G2 and curve G3 using a fitting function. Curve G2 is a cathode open-circuit potential theoretical curve computed from the content of the cathode active material in the lithium-ion rechargeable battery. Curve G3 is an anode open-circuit potential theoretical curve computed from the content of the anode active material in the lithium-ion rechargeable battery.

Next, an evaluation value calculation process is performed. The evaluation value calculation process calculates an evaluation value using an evaluation function evaluation function the evaluation value indicates a difference between the theoretical value SOC-voltage curve, which is obtained from curve G2 and curve G3, and the actual value SOC-voltage curve, which is shown as curve G1.

A shift amount parameter used in the fitting function to shift at least one of the cathode open-circuit potential theoretical curve and the anode open-circuit potential theoretical curve in an SOC direction is changed. At the same time, a scaling rate parameter used in the fitting function to adjust the length of at least one of the cathode open-circuit potential theoretical curve and the anode open-circuit potential theoretical curve in the SOC direction (horizontal axial direction) is changed. Then, an analysis process is performed. The analysis process repeatedly executes the theoretical value generation process and the evaluation value calculation process, and outputs the shift amount parameter that minimizes the evaluation value as the deterioration level of the lithium-ion rechargeable battery.

As shown in FIG. 3, a sideward shift amount ΔSOC1 of curve G3 and a length ΔSOC2 of curve G2 shown in the lower graph section of FIG. 3 are repeatedly adjusted until the curves match curve G1 shown in the upper graph section of FIG. 3.

In this fitting, the cell capacity (Ah) (known or measured) corresponds to a capacity CP shown in the lower graph section of FIG. 3. The capacity CP is a range in which the SOC determined by specific voltages (in the present embodiment, 3.0 V to 4.1 V) is 0% to 100%. A ratio of “ΔSOC1: CP” after the fitting may be calculated as a numerical value. This determines the length ΔSOC2 (Ah), which represents the capacity of the cathode.

The procedure described above completes the cathode capacity estimation step (S1) that estimates the capacity of the cathode in accordance with the present embodiment. In the present disclosure, the capacity of the cathode may be estimated by other methods.

### Battery Deterioration Level Estimation (S2)

Subsequently, the battery deterioration level is estimated (S2). This procedure corresponds to an example of a battery deterioration level estimation step in accordance with the present disclosure. However, there is no limitation to such a configuration.

In the battery deterioration level estimation step (S2), the battery deterioration level estimator 132, which is a program executed by the processor 13 of the control device 10, estimates the deterioration level of the lithium-ion rechargeable battery. The battery deterioration level estimator 132 uses the temperature T (K) of a subject lithium-ion rechargeable battery to calculate a side reaction current (A) occurring in the anode of the lithium-ion rechargeable battery. Then, the battery deterioration level estimator 132 uses the calculated side reaction current (A) to obtain a deterioration index of the lithium-ion rechargeable battery. Such a deterioration level estimation program includes a temperature obtainer, a side reaction current calculator, an ion concentration calculator, a decrease amount calculator, a capacity calculator, a coating thickness calculator, and a coating resistance calculator.

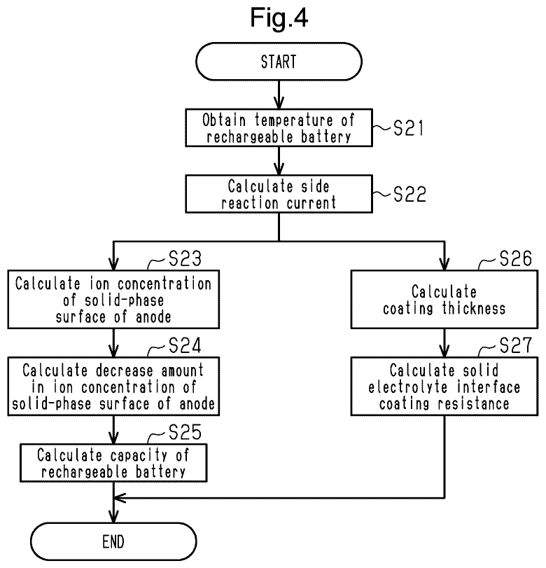

FIG. 4 is a flowchart illustrating an example of the process executed by the control device 10 in accordance with the deterioration level estimation program. The control device 10 repeatedly executes the process shown in FIG. 4 in predetermined sampling intervals.

In step S21, the temperature obtainer acquires the temperature T (K) of the lithium-ion rechargeable battery through the communication I/F 11 from a temperature sensor (not shown) that measures the temperature T (K) of the lithium-ion rechargeable battery. The temperature obtainer acquires the temperature T (K) of the lithium-ion rechargeable battery in predetermined time intervals. Hereafter, the time interval in which the temperature obtainer acquires the temperature T (K) of the lithium-ion rechargeable battery will be referred to as the sampling time. Also, the number of times the temperature obtainer acquires the temperature T (K) of the lithium-ion rechargeable battery will be referred to as the number of samplings.

In step S22, the side reaction current calculator uses the temperature T (K) of the lithium-ion rechargeable battery and predetermined equations to calculate the side reaction current occurring in the anode of the lithium-ion rechargeable battery.

The side reaction current calculator calculates the side reaction current I_{SEI} based on equation (1).

$$\begin{matrix}Equation 1 & \\ {I}_{SEI} ( k ) = Y ( \text{?} + \frac{Z + 1}{XY} ( {δ}_{SEI} ( k - 1 ) - {δ}_{SEI , INI} ) \text{?} & ( 1 )\end{matrix}$$

$$\text{?} \text{indicates text missing or illegible when filed}$$

The “k” represents a natural number indicating the number of samplings. The “δ_{SEI}” represents a coating thickness of a solid electrolyte interface (SEI) formed on the anode. The “δ_{SEI}” corresponds to a first coating thickness. The “δ_{SEI}(k−1)” represents the first coating thickness calculated by the coating thickness calculator, which will be described later, during a preceding sampling. The “δ_{SEI, INI}” represents an initial value of the first coating thickness of the solid electrolyte interface. The “t₀” represents a period over which an aging process was performed on the lithium-ion rechargeable battery. When k=1, δ_{SEI}(0) is the initial value δ_{SEI, INI}. In this case, I_{SEI}(1) may be expressed by equation (2). During the first sampling, the side reaction current calculator obtains the side reaction current I_{SEI}(1) shown in equation (2).

$$\begin{matrix}Equation 2 & \\ {I}_{SEI} ( 1 ) = {Yt}_{0}^{Z} & ( 2 )\end{matrix}$$

The “X” in equation (1) is a parameter defined by equation (3).

$$\begin{matrix}Equation 3 & \\ X = \frac{\frac{{M}_{SEI}}{{a}_{s , n} \times A \times {L}_{n} \times {ε}_{s , n} \times F}}{2 {ρ}_{SEI}} & ( 3 )\end{matrix}$$

The “M_{SEI}” represents a molecular weight (kg/mol) of the solid electrolyte interface. The “a_{s, n}” represents a specific surface area (cm²/cm³), which is a ratio of the surface area to the volume of the active material of the anode. The “A” represents an area (cm²) of the anode where the composite is applied. The “Lₙ” represents a thickness (cm) of the anode. The “ε_{s, n}” represents a volume fraction of the anode, which is a ratio of the volume of the active material excluding voids to the volume of the active material including the voids. The “F” represents the Faraday constant (C/mol). The “ρ_{SEI}” represents a density (kg/cm³) of the solid electrolyte interface.

The “Y” in equation (1) is a parameter determined by the temperature T (K) of the lithium-ion rechargeable battery and is defined by equation (4).

$$\begin{matrix}Equation 4 & \\ Y = exp ( {A}_{coeff} \times \frac{1}{T [ K ]} + {B}_{coeff} ) & ( 4 )\end{matrix}$$

The “Z” in equation (1) is a parameter determined by the temperature T (K) of the lithium-ion rechargeable battery and is defined by equation (5).

$$\begin{matrix}Equation 5 & \\ Z = {A}_{multi} ( T [ K ] - 273.15 ) + {B}_{multi} & ( 5 )\end{matrix}$$

The “Y” and “Z” are obtained as follows. Power approximation is performed on changes over time in the side reaction current at different temperatures T (K) (for example, 60° C., 70° C., 75° C., etc.) to obtain a power approximate equation of the side reaction current at each of the temperatures. The approximation of the changes in the side reaction current may be performed in accordance with a storage period and an aging period of the lithium-ion rechargeable battery. Subsequently, linear approximation is performed on the coefficient of the power approximate equation of the side reaction current at the different temperatures using an Arrhenius plot. The inclination of the obtained linear approximate equation corresponds to “A_{coeff}” in equation (4). The intercept of this linear approximate equation corresponds to “B_{coeff}” in equation (4).

Further, the multiplier of the power approximate equation of the side reaction current at each temperature is plotted on a graph having the horizontal axis indicate the temperature T (K). Then, linear approximation is performed. The inclination of the obtained linear approximate equation corresponds to “Aₘᵤₗₜᵢ” in equation (5). The intercept of this linear approximate equation corresponds to “Bₘᵤₗₜᵢ” in equation (5).

The parameters Y and Z are determined by the temperature T (K) of the lithium-ion rechargeable battery. The time to represents a period over which an aging process was performed on the lithium-ion rechargeable battery. The coating thickness calculator, which will be described later, calculates a past coating thickness δ_{SEI}. The initial value δ_{SEI, INI} is based on the coating thickness of the solid electrolyte interface. As shown in equation (1), the side reaction current calculator obtains the side reaction current based on parameters Y and Z, time t₀, past coating thickness δ_{SEI}, and initial value δ_{SEI, INI}. When calculating the side reaction current (I_{SEI}(2)) using the temperature T (K) of the lithium-ion rechargeable battery obtained during the first sampling (k=1), for example, the following process is executed. The side reaction current calculator uses the coating thickness (δ_{SEI}(1)) calculated by the coating thickness calculator based on the temperature T (K) of the lithium-ion rechargeable battery that is obtained during the first sampling to obtain the side reaction current (I_{SEI}(2)).

In step S23, the ion concentration calculator uses the side reaction current in the anode to calculate the present ion concentration of the solid-phase surface of the anode.

The ion concentration calculator calculates the present ion concentration of the solid-phase surface of the anode based on equations (6) and (7).

$$\begin{matrix}Equation 6 & \\ \frac{{dc}_{avg}}{dt} = - 3 \frac{{j}_{SEI}^{Li}}{{R}_{p}} & ( 6 )\end{matrix}$$

$$\begin{matrix}Equation 7 & \\ {c}_{s} = {c}_{avg} + \frac{{R}_{p}}{35 {D}_{s}} \times ( - {j}_{SEI}^{Li} ) & ( 7 )\end{matrix}$$

The “c_{avg}” represents an average Li concentration (mol/cm³) of the active material. The “Rₚ” represents a radius (cm) of the active material particles. The “cₛ” represents a Li concentration (mol/cm³) of the active material surface. The “Dₛ” represents a diffusion coefficient (cm²/s) of Li in the solid phase. The “j^{LI}_{SEI}” represents an ion flux of the solid-phase surface and is defined by equation (8).

$$\begin{matrix}Equation 8 & \\ {j}_{SEI}^{Li} = \{ \begin{matrix}- \frac{{I}_{SEI}}{\text{?} F \text{?} A} & ( Cathode Ion Flux ) \\ \frac{{I}_{SEI}}{\text{?} F \text{?} A} & ( Anode Ion Flux )\end{matrix} & ( 8 )\end{matrix}$$

$$\text{?} \text{indicates text missing or illegible when filed}$$

The “I_{SEI}” represents a side reaction current. The “aₛ” represents a surface area of the active material. The “F” represents the Faraday constant (C/mol). The “Lₚ” represents a thickness (cm) of the cathode. The “Lₙ” represents a thickness (cm) of the anode. The “A” represents an area (cm²) of the anode where the composite is applied.

In step S24, the decrease amount calculator obtains a decrease in the ion concentration of the solid-phase surface of the anode using the past ion concentration of the solid-phase surface of the anode and the present ion concentration of the solid-phase surface of the anode calculated in step S23.

The decrease amount calculator is a program that calculates a decrease in the ion concentration of the solid-phase surface of the anode using the past ion concentration of the solid-phase surface of the anode and the present ion concentration of the solid-phase surface of the anode calculated by the ion concentration calculator. Specifically, the decrease amount calculator may obtain a decrease in the ion concentration by subtracting the present ion concentration of the solid-phase surface of the anode from the past ion concentration.

When calculating the decrease in the ion concentration for the first time, the past ion concentration of the solid-phase surface of the anode is the initial value of the ion concentration of the solid-phase surface of the anode. When calculating the decrease in the ion concentration for the second time or for further subsequent times, the preceding ion concentration calculated by the ion concentration calculator is used as the past ion concentration of the solid-phase surface of the anode.

In general, a side reaction current flows when a solid electrolyte interface coating grows in an electrode. The present embodiment assumes that growth of such a solid electrolyte interface coating occurs mainly in the anode, and thus a side reaction current flows mainly in the anode. In this case, apparent discharging occurs only in the anode, thereby decreasing the ion concentration of the solid-phase surface of the anode.

### Displacement Between Corresponding Points of Cathode and Anode, and Correction of Displacement

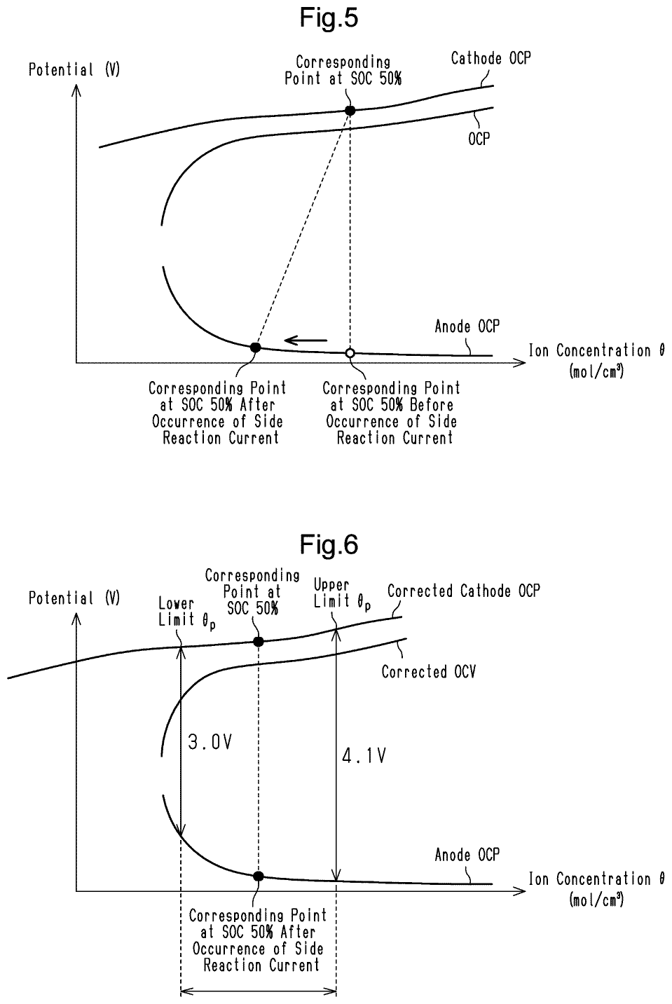

FIG. 5 is a diagram illustrating a displacement between corresponding points of the cathode and the anode caused by a change in the ion concentration of the solid-phase surface of the anode due to occurrence of a side reaction current, and the concept of correcting the displacement. FIG. 5 shows the open-circuit potential (OCP) of the cathode and the OCP of the anode before and after occurrence of a side reaction current in the anode, and the open-circuit voltage (OCV) that corresponds to a difference between the cathode OCP and the anode OCP.

In FIG. 5, the corresponding points of the cathode and the anode indicate the ion concentration and the potential of the cathode and the anode when the state of charge (SOC) is, for example, 50%. Before occurrence of a side reaction current, the corresponding points of the cathode and the anode indicate the same ion concentration. When a side reaction current occurs in the anode, the ion concentration of the solid-phase surface of the anode is reduced by the discharging. Hence, the corresponding points of the cathode and the anode are displaced. The decrease amount calculator calculates this decrease in the ion concentration of the solid-phase surface of the anode.

When the present OCV is lower than the estimated OCV with respect to a given cathode ion concentration rate θₚ (corresponding point on the cathode OCP in the drawing) and an anode ion concentration rate θₙ (corresponding point on the anode OCP in the drawing), the corresponding point on the anode OCP is displaced leftward. When the present OCV is higher than the estimated OCV with respect to a given cathode ion concentration rate θₚ and an anode ion concentration rate θₙ, the corresponding point on the anode OCP is displaced rightward. Such operations correspond to the deterioration level estimation. A greater amount of leftward displacement means a higher degree of deterioration.

The cathode ion concentration rate θₚ is obtained by “(1−present estimated lithium-ion concentration (c_{s, p, avg}))/(maximum lithium-ion concentration (c_{s, p, max}))”. As a result, the cell OCV curve is deformed. Therefore, corresponding points of θₚ-θₙ are adjusted in accordance with the specified voltages (for example, 3.0 V and 4.1 V).

FIG. 6 is a diagram showing a corrected lower limit cathode ion concentration rate θₚ and a corrected upper limit cathode ion concentration rate θₚ. The upper limit cathode ion concentration rate θₚ and the lower limit cathode ion concentration rate θₚ shown in FIG. 6 are obtained as described above.

In step S25, the capacity calculator obtains the present capacity (Ah) of the lithium-ion rechargeable battery using the decrease in the ion concentration of the solid-phase surface of the anode calculated in step S24.

The capacity calculator is a program that calculates the capacity (Ah) of the lithium-ion rechargeable battery using the decrease in the ion concentration of the solid-phase surface of the anode calculated by the decrease amount calculator. The capacity calculator corresponds to a deterioration index calculator.

Specifically, the capacity calculator corrects the cathode OCP in accordance with the decrease in the ion concentration of the anode solid-phase surface calculated by the decrease amount calculator. This correction corresponds to leftward shifting of the cathode OCP curve shown in FIG. 6. Subsequently, the capacity calculator calculates the ion concentration (mol) corresponding to the potential difference between the cathode OCP and the anode OCP when the SOC is 0%, and the ion concentration (mol) corresponding to the potential difference between the cathode OCP and the anode OCP when the SOC is 100%. In the example shown in FIG. 6, the potential difference between the cathode OCP and the anode OCP when the SOC is 0% is 3.0 V, and the potential difference between the cathode OCP and the anode OCP when the SOC is 100% is 4.1 V. Then, the capacity calculator substitutes the difference Liₐₘₒ of the ion concentration into equation (9) to calculate the capacity of the lithium-ion rechargeable battery.

$$\begin{matrix}Equation 9 & \\ Cell Capacity ( Ah ) = \frac{{Li}_{amo} [ mol ] \times F [ C / mol ]}{3600} & ( 9 )\end{matrix}$$

The “F” represents the Faraday constant.

In this manner, the capacity calculator obtains the capacity of the lithium-ion rechargeable battery after the capacity is reduced by the occurrence of the side reaction current in the anode. Alternatively, the capacity calculator may calculate the capacity of the lithium-ion rechargeable battery reduced by the occurrence of the side reaction current in the anode. Specifically, the capacity calculator may calculate a difference between the capacity before the occurrence of the side reaction current and the capacity after the occurrence of the side reaction current.

In the example shown in FIG. 6, the OCV curve is set so that two ends of the corrected OCV curve correspond to points at which the difference between the corrected cathode OCP curve and the anode OCP curve is 3.0 V and 4.1 V. However, the corrected OCV curve is not limited to that shown in FIG. 6.

In step S26, the coating thickness calculator obtains the first coating thickness and a second coating thickness of the anode.

The coating thickness calculator is a program that uses the side reaction current in the anode calculated by the side reaction current calculator to calculate the coating thickness of the solid electrolyte interface formed on the anode. The coating thickness calculator calculates a coating thickness δ_{SEI} and a coating thickness d_{W} (cm) of the solid electrolyte interphase of the anode based on equations (10) and (11). The coating thickness δ_{SEI} represents a coating thickness based on the relationship between a capacity decrease and a side reaction current. The coating thickness d_{W} represents a resistance distance based on the relationship between a resistance increase and a side reaction current, that is, a length that contributes to the resistance inside the coating. The coating thickness d_{W} corresponds to the second coating thickness.

$$Equation 10$$

$${δ}_{SEI} ( k ) = {δ}_{SEI} ( k - 1 ) + {XI}_{SEI} ( k ) Δ t \qquad ( 10 )$$

$$Equation 11$$

$${d}_{w} ( k ) = {d}_{w} ( k - 1 ) + W ( k ) {XI}_{SEI} ( k ) Δ t \qquad ( 11 )$$

The “k” represents a natural number indicating the number of samplings. The “I_{SEI}(k)” represents a side reaction current in the anode calculated by the side reaction current calculator using the temperature T (K) obtained during the “k”th sampling. The “δ_{SEI}(k)” represents the first coating thickness calculated using the side reaction current I_{SEI}(k). The “δ_{SEI}(k−1)” represents the first coating thickness calculated using the side reaction current I_{SEI}(k−1) based on the temperature T (K) obtained during the preceding sampling, that is, the “(k−1)”th sampling. The “d_{W}(k)” represents the second coating thickness calculated using the side reaction current I_{SEI}(k). The “d_{W}(k−1)” represents the second coating thickness calculated using the side reaction current I_{SEI}(k−1). The “d_{W}(0)” corresponds to an initial value (δ_{SEI, INI}) of the second coating thickness of the solid electrolyte interface. The “X” is a parameter defined by equation (3). The “Δt” represents the sampling time. The “W(k)” is a parameter defined by equation (12) and corresponds to a gain.

$$Equation 12$$

$$W ( k ) = {{Y}_{W} ( {t}_{0}^{2 - 1} + \frac{Z + 1}{XY} ( {δ}_{SEI} ( k - 1 ) - {δ}_{SEI , INI} ) )}^{\frac{Zw}{Z + 1}} \qquad ( 12 )$$

The “t₀” represents a period over which an aging process was performed on the lithium-ion rechargeable battery. The “δ_{SEI}(k−1)” represents a coating thickness of the solid electrolyte interface of the anode calculated using the side reaction current based on the temperature T (K) obtained during the preceding sampling. The “δ_{SEI, INI}” represents an initial value of the coating thickness of the solid electrolyte interface of the anode. The “X” is a parameter defined by equation (3). The “Y” is a parameter defined by equation (4). The “Z” is a parameter defined by equation (5).

The “Y_{W}” is a parameter determined by the temperature T (K) of the lithium-ion rechargeable battery and is defined by equation (13).

$$Equation 13$$

$${Y}_{w} = exp ( {A}_{coeff , w} \times \frac{1}{T [ K ]} + {B}_{coeff , w} ) \qquad ( 13 )$$

The “Z_{W}” is a parameter determined by the temperature T (K) of the lithium-ion rechargeable battery and is defined by equation (14).

$$Equation 14$$

$$Zw = {A}_{multi , w} ( T [ K ] - 273.15 ) + {B}_{multi , w} \qquad ( 14 )$$

The “A_{coeff, w}” and “B_{coeff, w}” in equation (13), and the “A_{multi, w}” and “B_{multi, w}” in equation (14) will now be described. Changes in an increase of a direct-current internal resistance (DCIR) over a predetermined period are obtained from measurement data of the DCIR of the lithium-ion rechargeable battery at different temperatures T (K). The used measurement data of the direct-current internal resistance of the lithium-ion battery is obtained, for example, over a storage period at 60° C., 70° C., 75° C., and 80° C. Such measurement data is used to calculate the increase in the direct-current internal resistance with respect to a corresponding initial value at each temperature T (K). Then, power approximation is performed on the changes over time in the increase in the direct-current internal resistance at each temperature T (K).

Further, an increase ΔR_{SEI} in a solid electrolyte interface coating resistance is calculate based on the following equation (15).

$$Equation 15$$

$$Δ {R}_{SEI} = {R}_{SEI} ( k ) - {R}_{SEI} ( 0 ) \qquad ( 15 )$$

The “R_{SEI}(0)” represents an initial value of the direct-current internal resistance.

The “R_{SEI}(k)” represents a solid electrolyte interface coating resistance and is defined by the following equation (16).

$$Equation 16$$

$${R}_{SEI} ( k ) = \frac{{d}_{w} ( k )}{( {a}_{s , n} \times A \times {L}_{m} \times {ε}_{s , n} ) \times {κ}_{SEI}} [ Ω ] \qquad ( 16 )$$

The “k” represents a natural number indicating the number of samplings. The “d_{W}(k)” represents the second coating thickness defined by equation (11). The “a_{s, n}” represents a specific surface area (cm²/cm³), which is a ratio of the surface area to the volume of the active material of the anode. The “A” represents an area (cm²) of the anode where the composite is applied. The “Lₙ” represents a thickness (cm) of the anode. The “ε_{s, n}” represents a volume fraction of the anode, which is a ratio of the volume of the active material excluding voids to the volume of the active material including the voids. The “κ_{SEI}” represents an ion conductivity (S/cm) in the solid electrolyte interface coating.

Accordingly, equation (15) is defined as equation (17).

$$Equation 17$$

$$Δ {R}_{SEI} = \frac{{d}_{w} ( k - I ) + W ( k ) {XI}_{SEI} ( k ) Δ t}{( {a}_{s , n} \times A \times {L}_{n} \times {ε}_{s , n} ) \times {κ}_{SEI}} {R}_{SEI} ( 0 ) \qquad ( 17 )$$

The increase ΔR_{SEI} in the solid electrolyte interface coating resistance is defined by equation (17). Power approximation is performed on the increase in the direct-current internal resistance based on the measurement data. The increase ΔR_{SEI} in the solid electrolyte interface coating resistance calculates the gain W(k) at different temperature T (K) over the storage period of the lithium-ion rechargeable battery such that the increase ΔR_{SEI} matches the increase in the direct-current internal resistance. The temperatures T (K) are, for example, 60° C., 70° C., 75° C., and 80° C. Subsequently, power approximation is performed on the obtained gain W(k) at each temperature T (K) to obtain a power approximate equation of the gain W(k) at each temperature T (K). Then, linear approximation is performed on the coefficient of the power approximate equation of the gain W(k) at the different temperatures T (K) using an Arrhenius plot. The inclination of the obtained linear approximate equation corresponds to “A_{coeff, w}” in equation (13). The intercept of this linear approximate equation corresponds to “B_{coeff, w}” in equation (13).

In the same manner, the multiplier of the power approximate equation of the gain W(k) at each temperature T (K) is plotted on a graph having the horizontal axis indicate the temperature T (K). Then, linear approximation is performed. The inclination of the obtained linear approximate equation corresponds to “A_{multi, w}” in equation (14). The intercept of this linear approximate equation corresponds to “B_{multi, w}” in equation (14).

The coating thickness calculator obtains “Y_{W}” based on equation (13) using the above-described “A_{coeff, w}”, “B_{coeff, w}”, and the temperature T (K) of the lithium-ion rechargeable battery. Further, the coating thickness calculator obtains “Z_{W}” based on equation (14) using the above-described “A_{multi, w}”, “B_{multi, w}”, and the temperature T (K) of the lithium-ion rechargeable battery. Next, the coating thickness calculator obtains the gain W(k) based on equation (12) using the above-described “Y_{W}” and “Z_{W}”. Then, the coating thickness calculator obtains the second coating thickness d_{W} of the solid electrolyte interface of the anode based on equation (11) using the gain W(k).

In step S27, the coating resistance calculator obtains the solid electrolyte interface coating resistance (Ω) using the second coating thickness d_{W} of the solid electrolyte interface of the anode calculated by the coating thickness calculator. The coating resistance calculator may calculate the solid electrolyte interface coating resistance R_{SEI} based on equation (16).

### Cathode Ion Concentration Rate θₚ Estimation (S3)

Subsequently, the cathode ion concentration rate θₚ is estimated (S3). This procedure corresponds to an example of an ion concentration rate θ estimation step in accordance with the present disclosure. However, there is no limitation to such a configuration. As described above, the ion concentration rate θ is estimated by the battery deterioration level estimation step (S2). However, in the present step, the ion concentration rate θ is estimated without taking into consideration the coating thickness of the solid electrolyte interface (SEI).

The cathode ion concentration estimator 133 is configured to calculate a solid-phase potential difference of the cathode and a solid-phase potential difference of the anode in a thickness-wise direction of the lithium-ion rechargeable battery using a solid-phase diffusion model of the lithium-ion rechargeable battery.

Equation (18) is a solid-phase diffusion equation that serves as an example of the solid-phase diffusion model.

$$Equation 18$$

$$\frac{δ c}{δ t} = \frac{1}{{r}^{2}} \frac{δ}{δ r} ( {D}_{s} {r}^{2} \frac{δ c}{δ r} ) \qquad ( 18 )$$

The “c” represents a lithium-ion concentration (mol/m³) of the active material.

The “t” represents time.

The “r” represents a position of the active material in a particle radial direction.

The “Dₛ” represents a diffusion coefficient (m²/s) of the lithium ions in the solid phase.

Equation (19) indicates a boundary condition of the solid-phase diffusion model of equation (18).

$$Equation 19$$

$$\begin{matrix}- {D}_{s} \frac{δ {c}_{s}}{δ r} {\vert}_{\begin{matrix}= {j}^{Li} \\ r = {R}_{p}\end{matrix}} \\ \frac{δ {c}_{s}}{δ r} {\vert}_{r = 0} = 0\end{matrix} \qquad ( 190$$

The “cₛ” represents a lithium-ion concentration (mol/m³) of the active material surface.

The “Rₚ” represents a surface position of the active material in the particle radial direction.

The “j^{Li}” represents a lithium-ion flux (mol/m²).

The solid-phase diffusion model of equation (18) may be obtained by approximating a concentration distribution of the lithium ions in the active material with a quartic polynomial, and expressing a difference between an average lithium-ion concentration “c_{avg}” of the active material and a lithium-ion concentration “cₛ” of the active material surface by a first-order lag model.

The average lithium-ion concentration “c_{avg}” (mol/m³) of the active material may be expressed using equation (20).

$$Equation 20$$

$$\frac{{dc}_{avg}}{dt} = - 3 \frac{{j}^{Li}}{{R}_{p}} \qquad ( 20 )$$

A lithium-ion concentration flux “q” (mol/m³) of an average volume of the active material may be expressed using equation (21).

$$Equation 21$$

$$\frac{dq}{dt} = - 30 \frac{D}{{R}_{p}^{2}} q \frac{45}{2} \frac{{j}^{Li}}{{R}_{p}^{2}} \qquad ( 21 )$$

The lithium-ion flux “j^{Li}” may be expressed using equation (22).

$$Equation 22$$

$${j}^{Li} = ( \begin{matrix}- \frac{I}{{a}_{s} {FL}_{p} A} ( Cathode ) \\ \frac{I}{{a}_{s} {FL}_{w} A} ( Anode )\end{matrix} \qquad ( 22 )$$

The “I” represents a current.

The “as” represents a surface area (ratio area) (1/m) of the active material per volume and may be expressed by “aₛ=3εₛ/Rₚ”.

The “F” represents the Faraday constant.

The “Lₚ” represents a thickness (m) of the cathode.

The “Lₙ” represents a thickness (m) of the anode.

The “A” represents a reactive area (m²) of an electrode.

In this manner, the lithium-ion concentration “cₛ” of the active material surface may be expressed using equation (23).

$$Equation 23$$

$${c}_{s} = {c}_{avg} + \frac{Rp}{35 {D}_{s}} ( 8 {D}_{s} q - {j}^{Li} ) \qquad ( 23 )$$

The cathode ion concentration rate θₚ may be obtained from the solid-phase lithium concentration “c_{s, p}” (mol/cm³) of the cathode and the solid-phase maximum ion concentration “c_{s, p, max}” (mol/cm³) of the cathode using equation (24). In the present embodiment, “c_{s, p, avg}” (mol/cm³) is used as “c_{s, p}”. The “c_{s, p, max}” (mol/cm³) represents the solid-phase maximum ion concentration of the cathode. The “c_{s, p, max}” is a physical property value determined by the cathode active material. Also, “c_{s, p, avg}” (mol/cm³) represents the solid-phase average lithium concentration of the cathode. The lithium-ion concentration “cₛ” (mol/cm³) of the active material surface of the cathode is obtained from equation (23).

$$Equation 24$$

$$θ p = 1 - \frac{Cs , p}{Cs , p , max} \qquad ( 24 )$$

### Plotting Battery Cell CB on θ-Axis (S4)

First, the cathode ion concentration rate θₚ of each battery cell CB is plotted on the θ-axis (S4). This procedure corresponds to an example of a battery cell plotting step in accordance with the present disclosure. The method using the cathode ion concentration rate θₚ will now be described. In the present embodiment, the cathode is used in the description as an example. However, the same calculation can be performed with the anode by simply reversing the left and right. Specifically, although the cathode ion concentration rate θₚ becomes equal to 0 when the cathode SOC=100%, the anode ion concentration rate θₙ becomes equal to 0 when the anode SOC=0%.

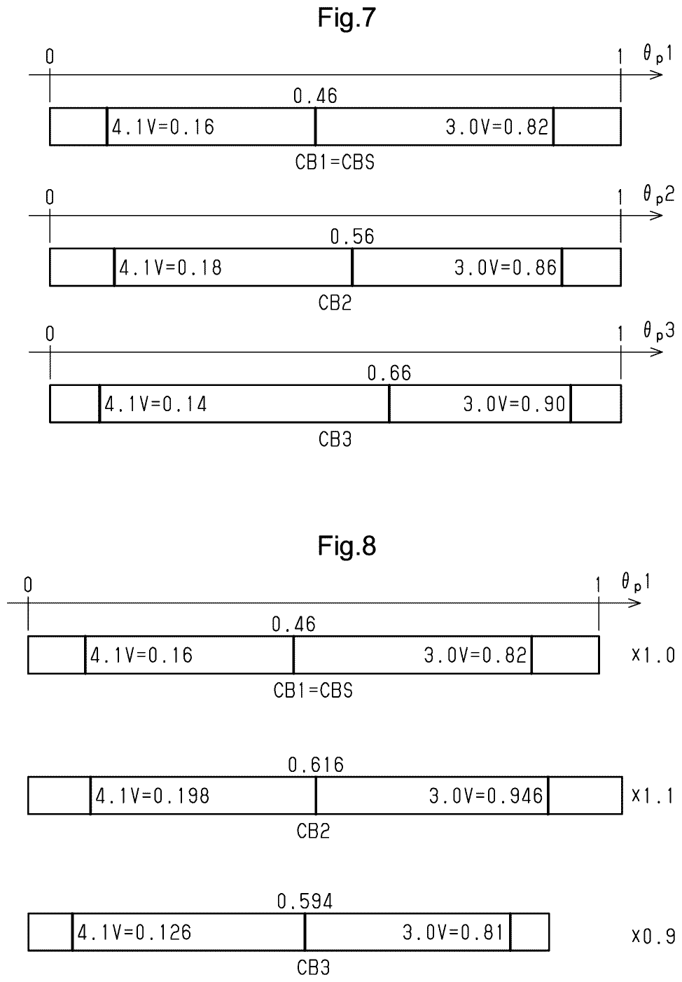

FIG. 7 is a diagram showing the cathode ion concentration rate θₚ is plotted as a θ coordinate. The θ coordinate refers to the ion concentration rate θ indicated as a position on a straight line. The cathode ion concentration rate θₚ is obtained by “1−cathode Li concentration/maximum Li concentration”, and is a ratio (0 to 1) defined by the above-described equation (24). The upper limit cathode ion concentration rate θₚ and the lower limit cathode ion concentration rate θₚ shown in FIG. 6 are plotted as θ coordinates.

In FIG. 7, the cathode ion concentration rate θₚ=0 is indicated as the lower limit voltage 3.0 V, and the cathode ion concentration rate θₚ=1 is indicated as the upper limit voltage 4.1 V. The cathode active material SOC may be expressed by the above-described cathode ion concentration rate θₚ. At this time, a ratio of the cathode ion concentration rate θₚ of each of the battery cells CB1 to CB3 and the corresponding SOC (%) is 1:1.

In the present embodiment, the actual battery module includes a large number of battery cells CB. However, in order to facilitate illustration, the multiple battery cells CB are simplified by the three battery cells CB1 to CB3. Further, any one of the battery cells CB is designated as the reference battery cell CBS. The reference battery cell CBS serves as the reference for comparison between the multiple battery cells CB, and any battery cell CB may be selected as the reference battery cell CBS. In the present embodiment, the battery cell CB1 serves as the reference battery cell CBS. In FIG. 7, the band-shaped graphical representations related to the battery cells CB1 to CB3 will be referred to as “bars” for the sake of convenience.

### Battery Capacity Correction (S5)

Next, the battery capacity is corrected (S5) using the θ coordinates. This procedure corresponds to an example of a battery capacity correction step in accordance with the present disclosure.

FIG. 8 is a diagram illustrating the battery capacity correction step performed on the cathode ion concentration rate θₚ plotted as θ coordinates. The length of each bar is adjusted in accordance with a ratio of the cathode capacity of each of the battery cells CB1 to CB3 with respect to the reference battery cell CBS. In this case, the cathode capacity refers to the cathode capacity obtained by the cathode capacity estimation step (S1) or the cathode capacity corrected in accordance with the deterioration level obtained by the battery deterioration level estimation step (S2).

The length of each bar is extended or reduced with reference to the length of the reference battery cell CBS (here, battery cell CB1) that serves as a battery cell having the reference length value of 1. At this time, the ratio of the cathode ion concentration rate θₚ and the SOC (%) on the θ-axis becomes no longer 1:1.

In the example of the present embodiment, the cathode capacity of the battery cell CB2 is 1.1 times the cathode capacity of the battery cell CB1, and the cathode capacity of the battery cell CB3 is 0.9 times the cathode capacity of the battery cell CB1. In this case, the reference θ coordinate is the θ coordinate of the battery cell CB1, which is the reference battery cell CBS. The length of each bar is adjusted using the position at which the cathode ion concentration rate θₚ of the reference battery cell CBS is 0 as the reference. More specifically, the length of the battery cell CB2 is set to 1.1 times the length of the battery cell CB1, and the length of the battery cell CB3 is set to 0.9 times the length of the battery cell CB1. In this case, the left ends of the bars representing the battery cells CB1 to CB3 are aligned with one another at the same position. This adjustment of the bar length displaces the battery cells CB2 and CB2 with respect to the reference battery cell CBS. Therefore, numerical values, such as the SOC (%) or the cathode ion concentration rate θₚ, no longer have physical meanings, except for those of the reference battery cell CBS.

Position Adjustment in Accordance with Cathode Ion Concentration Rate θₚ (S6)

Next, the positions of the battery cells CB2 and CC3 are adjusted in accordance with the cathode ion concentration rate θₚ of the reference battery cell CBS (S6). This procedure corresponds to an example of an ion concentration rate θ position adjustment step in accordance with the present disclosure.

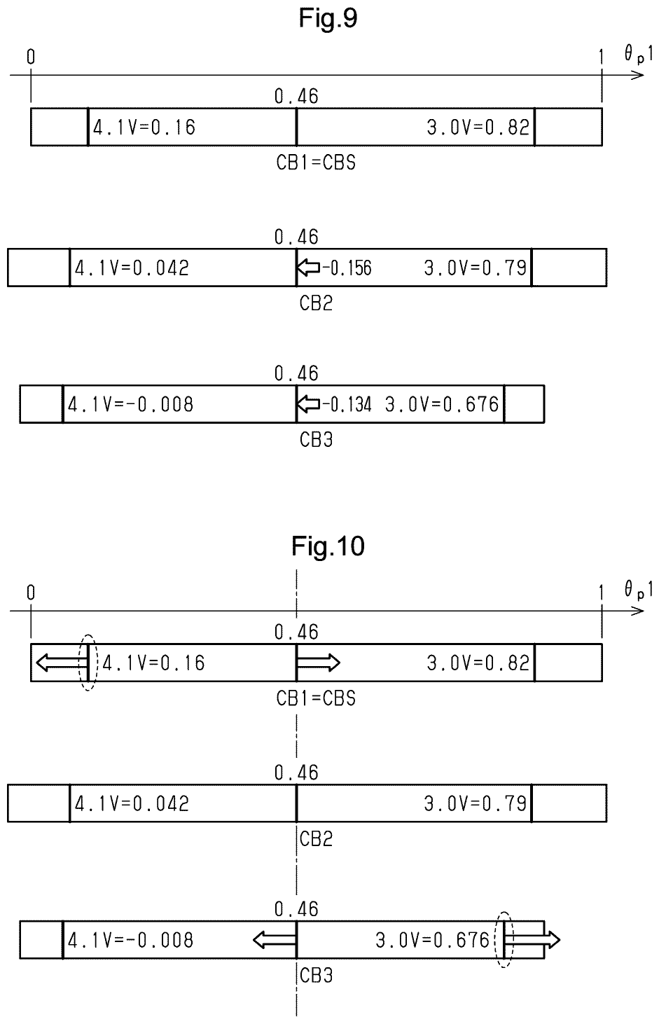

FIG. 9 is a diagram illustrating the position adjustment of the battery cells CB2 and CB3 in accordance with the cathode ion concentration rate θₚ of the reference battery cell CBS.

The positions of the cathode ion concentration rate θₚ have been displaced by the battery capacity correction step (S5). Accordingly, the positions of the battery cells CB2 and CB3 are adjusted in accordance with the position of the cathode ion concentration rate θₚ of the reference battery cell CBS.

More specifically, the battery cell CB2 has the cathode ion concentration rate θₚ of 0.616, and thus the position of the bar of the battery cell CB2 is shifted by −0.156, or 0.156 leftward, to match the position of the cathode ion concentration rate θₚ=0.46 of the reference battery cell CBS. This aligns the position of the cathode ion concentration rate θₚ=0.46 of the battery cell CB2 with the position of the cathode ion concentration rate θₚ=0.46 of the reference battery cell CBS. As a result, the cathode ion concentration rate θₚ=0.198 at the upper limit voltage=4.1 V is changed to the cathode ion concentration rate θₚ=0.042. Also, the cathode ion concentration rate θₚ=0.946 at the lower limit voltage=3.0 V is changed to the cathode ion concentration rate θₚ=0.79.

The battery cell CB3 has the cathode ion concentration rate θₚ of 0.594, and thus the position of the bar of the battery cell CB3 is shifted by −0.134, or 0.134 leftward, to match the position of the cathode ion concentration rate θₚ=0.46 of the reference battery cell CBS. This aligns the position of the cathode ion concentration rate θₚ=0.46 of the battery cell CB3 with the position of the cathode ion concentration rate θₚ=0.46 of the reference battery cell CBS. As a result, the cathode ion concentration rate θₚ=0.126 at the upper limit voltage=4.1 V is changed to the cathode ion concentration rate θₚ=−0.008. Also, the cathode ion concentration rate θₚ=0.81 at the lower limit voltage=3.0 Vis changed to the cathode ion concentration rate θₚ=0.676.

### Battery Cell Voltage Adjustment (S7)

FIG. 10 is a diagram illustrating voltage adjustment of the battery cells CB (S7).

Next, the voltages of the battery cells CB are adjusted (S7). This procedure corresponds to an example of a battery cell voltage adjustment step in accordance with the present disclosure.

In a battery module SOC estimation step (S8), which will be described later, the battery module is controlled using a range between the highest lower limit voltage (V) of the battery cells CB and the lowest upper limit voltage of the battery cells CB as the SOC range of 0% to 100% of the battery module.

The SOC range of 0% to 100% of the battery module may be expanded if the highest lower limit voltage (V) of the battery cells CB becomes lower and the lowest upper limit voltage (V) of the battery cells CB becomes higher.

Accordingly, after the position adjustment step (S6) is performed in accordance with the cathode ion concentration rate θₚ, one of the battery cells CB1 to CB3 having the highest lower limit voltage (V) is charged. Also, one of the battery cells CB1 to CB3 having the lowest upper limit voltage (V) is discharged. In this manner, the cathode ion concentration rate θₚ at the highest lower limit voltage (V) of the battery cells CB becomes lower, and the cathode ion concentration rate θₚ at the lowest upper limit voltage (V) of the battery cells CB becomes higher. This expands the distance between the highest lower limit voltage (V) and the lowest upper limit voltage (V) of the battery cells CB. That is, the battery module will be charged and discharged within a wider range.

The present procedure is optional. Furthermore, the present procedure may be performed after setting threshold values for a certain determination.

When the first execution of the charging or discharging changes the battery cell CB having the highest lower limit voltage or the battery cell CB having the lowest upper limit voltage, the same procedure may be repeated.

### Battery Module SOC Estimation (S8)

When the voltage adjustment of the battery cells CB (S7) is completed, the battery module SOC is estimated (S8). This procedure corresponds to an example of a battery module SOC estimation step in accordance with the present disclosure.

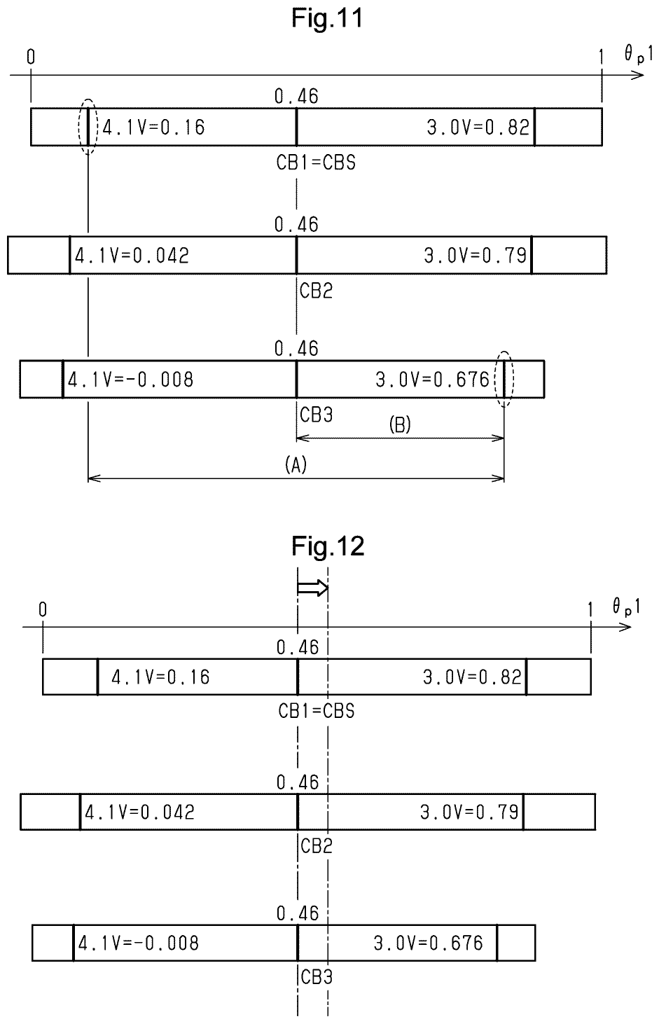

FIG. 11 is a diagram illustrating the battery module SOC estimation step (S8). When the voltage adjustment step (S7) is not previously performed on the battery cells CB in the state shown in FIG. 9, the cathode ion concentration rate θₚ at the highest upper limit voltage 4.1 V of the battery cell CB1 is 0.16. Also, the cathode ion concentration rate θₚ at the lowest lower limit voltage 3.0 V of the battery cell CB3 is 0.676. The range (A) between θₚ=0.16 and θₚ=0.676 is used as the usable range of the battery module. Specifically, θₚ=0.16 serves as SOC=100% of the battery module, and θₚ=0.676 serves as SOC=0% of the battery module. Also, the range (A) expressed in (Ah) corresponds to the fully-charged capacity (Ah) of the battery module. In this case, the SOC (%) of the battery module may be calculated as follows.

$$\begin{matrix}Battery Module SOC = ( B ) / ( A ) \\ = ( 0.46 - 0.676 ) / ( 0.16 - 0.676 ) \times 100 \\ ( nearly equal ) 42 \%\end{matrix}$$

The SOC (%) of the battery module is estimated through the above-described procedure from the cathode capacity estimation step (S1) through the battery module SOC estimation step (S8). Then, charging and discharging of the battery module is controlled based on this SOC value (%).

### Simplified SOC Estimation (S9)

As described above, the procedure from the cathode capacity estimation step (S1) to the battery module SOC estimation step (S8) estimates the SOC (%) of the battery module. Then, the estimated SOC value (%) is used to control charging and discharging of the battery module. In the present embodiment, a simplified SOC estimation (S9) is performed to facilitate the processing. This reduces the control load and increases the processing speed. The present procedure corresponds to an example of a simplified SOC estimation step in accordance with the present disclosure.

FIG. 12 is a diagram illustrating the simplified SOC estimation step (S9). In a relatively short period of time, the battery cells CB1 to CB3 have a limited amount of changes in the battery capacity or the deterioration level. Accordingly, the battery cells CB1 to CB3 have substantially synchronized changes in the cathode ion concentration rate θₚ in the short period of time. Specifically, in a relatively short period of time, the cathode ion concentration rate θₚ of the battery cells CB1 to CB3 change by substantially the same amount with almost no difference, as shown in FIG. 12. That is, the coordinates of the cathode ion concentration rate θₚ of the battery cells CB1 to CB3 move sideward by substantially the same amount. Thus, for a while, only the SOC of the battery cell CB1 may be estimated, and it may be considered that the changes in the SOC of the other battery cells CB2 and CB3 are equivalent to that of the battery cell CB1. This may reduce the calculation load by the SOC estimation and increase the control speed.

The simplified SOC estimation step (S9) is repeated until a predetermined time (for example, 60 seconds) elapses (S10: NO), and is ended when the predetermined time elapses (S10: YES).

### Anomalous Battery Cell Determination (S11)

When the predetermined time elapses (S10: YES) and the simplified SOC estimation step (S9) is completed, an anomalous battery cell is determined (S11). This procedure corresponds to an example of an anomalous battery cell determination step in accordance with the present disclosure.

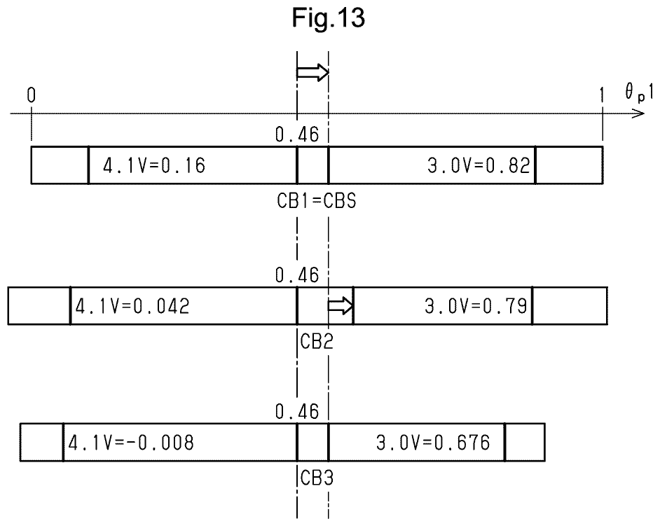

FIG. 13 is a diagram showing the anomalous battery cell determination step (S11). As described above, in a relatively short period of time, the battery cells CB1 to CB3 have a limited amount of changes in the battery capacity or the deterioration level. Accordingly, the battery cells CB1 to CB3 have substantially synchronized changes in the cathode ion concentration rate θₚ in the short period of time. However, when a specific battery cell CB (here, battery cell CB2) has a greater amount of change in the cathode ion concentration rate θₚ than the other battery cells CB, as shown in FIG. 13, it may be assumed that self-discharging or the like is occurring in the specific battery cell CB. Accordingly, when a specific battery cell CB has a greater amount of change in the cathode ion concentration rate θₚ than the other battery cells CB, that is, when the cathode ion concentration rate θₚ of a specific battery cell CB moves further rightward in the drawing, the specific battery cell CB is determined to be anomalous.

### Processing Ending Determination (S12)

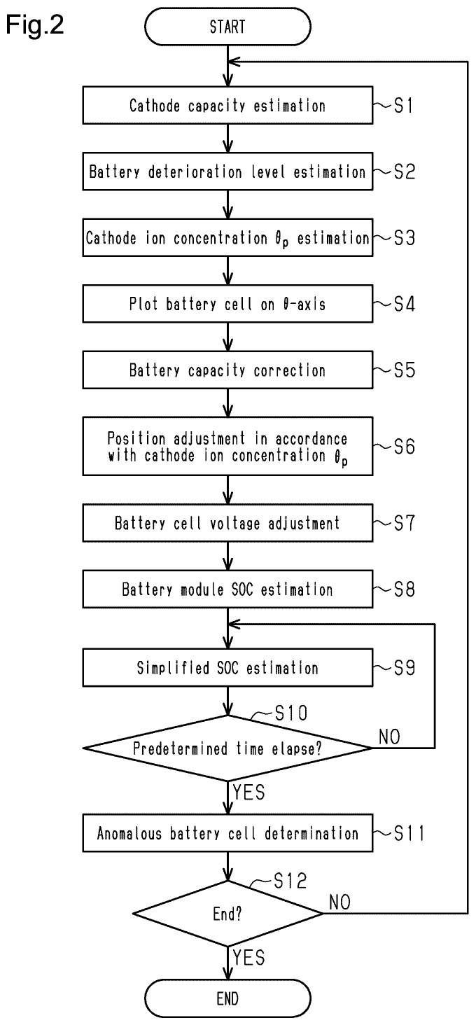

The control method of the present embodiment is ended, for example, when the vehicle operation is ended or when an affirmative determination is given (S12: YES) in the anomalous battery cell determination (S11). Otherwise (S12: NO), the control method of the present embodiment is repeated. In this case, the control device 10 does not have to return to the cathode capacity estimation step (S1) as shown in FIG. 2, and may return to, for example, the cathode ion concentration rate θₚ estimation step (S3).

### Operation of the Present Embodiment

In the present embodiment, the cathode ion concentration rate θₚ of the cathode active material in each battery cell CB is used to perform an absolute evaluation on the state of the battery cell CB. Then, the SOCs (%) of the battery cells CB are compared using the respective cathode ion concentration rates θₚ.

On such a premise, the battery module can be controlled so that the battery module SOC (%) changes in the same manner regardless of whether the battery module SOC (%) is in a relatively high region or a relatively low region, without applying a relatively large load to some of the battery cells CB or imposing unnecessary restrictions on the battery cells CB. This allows for prediction of when the battery module becomes fully charged or fully discharged. Therefore, the battery module is effectively controlled within its performance range without applying an excessive load to the battery cells CB.

### Advantages of the Present Embodiment

(1) With the method for controlling a battery module of rechargeable batteries in accordance with the present disclosure, the battery module SOC changes in the same manner in response to the same input/output current even when the battery cells CB forming the battery module vary in the SOC. This also allows for prediction of when the battery module becomes fully charged or fully discharged.

(2) In the method for controlling a battery module of the present embodiment, the control device 10 estimates the ion concentration rate θₚ of the cathode active material in each of the battery cells CB1 to CB3 in the ion concentration rate θ estimation step. This allows for accurate evaluation of the battery cells CB1 to CB3 using the cathode ion concentration rate θₚ, which is a physical quantity.

(3) Among the battery cells CB1 to CB3, the battery cell CB1 is designated as the reference battery cell CBS, and the remaining battery cells CB each serve as a non-reference battery cell CB. The estimated cathode ion concentration rates Op of the battery cells CB2 and CB3 are plotted on the common θ-axis. This allows for comparison of the battery cells CB1 to CB3 based on the cathode ion concentration rate θₚ.

(4) The length of each of the non-reference battery cells CB2 and CB3 is adjusted in accordance with the length of the reference battery cell CBS that serves as a battery cell having the reference length value of 1. Each length represents the capacity of a corresponding battery cell CB. This allows for comparison of the cathode ion concentration rate θₚ of the cathode active material in the battery cells CB1 to CB3 taking into consideration the battery capacity.

(5) The position of the cathode ion concentration rate θₚ of each of the non-reference battery cells CB2 and CB3 is shifted to agree with the position of the cathode ion concentration rate θₚ of the reference battery cell CBS on the θ-axis. This allows for accurate comparison of the cathode ion concentration rate θₚ of the battery cells CB1 to CB3.

(6) The SOC (%) of the battery module is estimated using a range between the cathode ion concentration rate θₚ at the lowest upper limit voltage of the battery cells CB1 to BC3 and the cathode ion concentration rate θₚ at the highest lower limit voltage of the battery cells CB1 to CB3 as an SOC range of 100% to 0% of the battery module. This allows for optimal control on charging and discharging of the battery module without applying an excessive load on any of the battery cells CB1 to CB3.

(7) In the ion concentration rate θ estimation step that estimates the cathode ion concentration rate θₚ of the cathode active material, the solid-phase potential difference of the cathode and the solid-phase potential difference of the anode in the thickness-wise direction of the battery is calculated using the solid-phase diffusion model of the lithium-ion rechargeable battery. Further, the difference between the average ion concentration of the active material and the ion concentration of the active material surface is expressed by a first-order lag model. The ion concentration of the active material surface is obtained from the average ion concentration of the active material and the ion concentration flux of the average volume of the active material. The ion concentration rate θ is estimated from the average ion concentration of the active material surface and the solid-phase maximum ion concentration.

This allows for accurate estimation of the cathode ion concentration rate θₚ of the cathode active material in the battery cells CB1 to CB3.

(8) Before the cathode ion concentration rate θₚ estimation step, the capacity estimation step and the deterioration level estimation step are executed. The capacity estimation step estimates the capacity of an electrode plate of each of the battery cells CB1 to CB3. The deterioration level estimation step estimates the deterioration level of each battery cell CB. This allows for accurate estimation of the cathode ion concentration rate θₚ of each of the battery cells CB1 to CB3 taking into consideration the capacity of the electrode plate and the deterioration level of each of the battery cells CB1 to CB3. The present disclosure is also applicable to a lithium-ion rechargeable battery having a use history in the vehicle.

(9) After the battery module SOC estimation step, the simplified SOC estimation step is performed. The simplified SOC estimation step estimates the SOC based on only the cathode ion concentration rate θₚ of the reference battery cell CBS. This allows the battery module SOC (%) to be processed with a relatively small amount of processing load at a relatively high processing speed.

(10) The anomalous battery cell determination step is performed to determine any of the battery cells CB1 to CB3 to be anomalous if the battery cell CB has a greater amount of change in the SOC, which is estimated based on the cathode ion concentration rate θₚ, than the other battery cells CB. This allows for detection of the battery cell CB having an anomaly caused by self-discharging or the like.

(11) Before the battery module SOC estimation step, the battery cell voltage adjustment step is performed. The battery cell voltage adjustment step charges one of the battery cells CB1 to CB3 having the lowest upper limit voltage or discharges one of the battery cells CB1 to CB3 having the highest lower limit voltage. This expands the control range of the battery module and allows the battery module to be used efficiently.

(12) In the capacity estimation step that estimates the capacity of an electrode plate of each battery cell CB, the actual value acquisition process is executed. Further, the theoretical value SOC-voltage curve, which is calculated from the difference between the cathode open-circuit potential theoretical curve and the anode open-circuit potential theoretical curve, is generated using the fitting function. The evaluation value is calculated using the evaluation function for calculating the evaluation value indicates the difference between the theoretical value SOC-voltage curve and the actual value SOC-voltage curve. Then, the shift amount parameter that minimizes the evaluation value while the shift amount parameter and the scaling rate parameter are being changed is output as the deterioration level of the battery cell.

This allows for accurate estimation of the capacity of the electrode plate of each battery cell CB, which serves as the premise for the estimation of the cathode ion concentration rate θₚ.

(13) In the deterioration level estimation step that estimates the deterioration level of each battery cell CB, the side reaction current occurring in the anode of the battery cell CB is calculated using the temperature T (K) of the rechargeable battery. Then, the deterioration index of the battery cell CB is calculated based on the obtained side reaction current. This allows for accurate estimation of the deterioration level of each battery cell CB, which serves as the premise for the estimation of the cathode ion concentration rate θₚ.

(14) As described in the present embodiment, the method for controlling a battery module in accordance with the present embodiment is most effective when the electrode plate is the cathode and the rechargeable battery is a lithium-ion rechargeable battery.

### Modified Examples

The present disclosure is not limited to the above embodiment and may be modified as follows.

In the method for controlling a battery module in accordance with the present embodiment, the battery module described as an example is included in a battery pack that is installed in a battery electric vehicle, a hybrid electric vehicle, or the like, for driving the vehicle. However, there is no limitation to such a configuration, and any combination of battery cells CB used as a battery module may be employed.

In the present embodiment, lithium ions Li⁺ in the cathode of the lithium-ion rechargeable battery are described as an example. However, there is no limitation to such a configuration, and any combination of rechargeable battery cells forming a battery module may be employed. The rechargeable battery may be other type of non-aqueous electrolyte solution rechargeable battery, an alkaline electrolyte solution rechargeable battery such as a nickel-metal hydride battery (NiMH), a solid-state battery, or the like.

In the present embodiment, the capacity estimation step, which estimates the capacity of the electrode plate of the battery cell CB, and the deterioration level estimation step, which estimates the deterioration level of the battery cell CB, are executed in different steps. However, these steps may be executed in a single step. A long as the battery capacity is analyzed taking into consideration the deterioration level of the battery, the objective of the present disclosure will be achieved.

Further, the cathode ion concentration rate θₚ of the cathode is described as an example. Alternatively, an anode ion concentration rate θₙ of the anode may be used. In this case, when the open-circuit voltage OCV (V) of the battery module increases, lithium ions Li⁺ are stored in the anode active material of the anode, thereby increasing the anode ion concentration rate θₙ of the anode. Therefore, the sideward movement of the θ coordinates of the cathode ion concentration rate θₚ shown in FIGS. 7 to 13 will be reversed.

In the present embodiment, three battery cells CB1 to CB3 are described as an example of multiple battery cells CB. However, there is no limitation to such a structure. In actuality, a large number of battery cells CB are included in a single battery module.

The control device 10 shown in FIG. 1 is merely an example. The control device 10 may have any configuration as long as the procedure of the present disclosure is performed. For example, a communication means outside the vehicle may perform the procedure.

The flowcharts shown in FIGS. 2 and 4 are merely examples of the present disclosure. One skilled in the art may add, remove, replace, or modify the steps in the flowcharts shown in FIGS. 2 and 4.

For example, when it is determined to not end the process of the flowchart shown in FIG. 2 (S12: NO), the control device 10 may return to the battery deterioration level estimation step (S2), instead of the cathode capacity estimation step (S1). Furthermore, execution of each step may be determined based on a predetermined threshold value, such as an elapsed time, the SOC (%), the ion concentration rate θ, or the like.

The numerical values, numerical ranges, graphs, and the like described in the present embodiment are merely examples for explanation of the present disclosure, and may be optimized by one skilled in the art.

It should be apparent to those skilled in the art that the present disclosure may be embodied in many other specific forms without departing from the spirit or scope of the disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A method for controlling a battery module in which battery cells of a rechargeable battery are combined, the method comprising:
estimating, by a control device, an ion concentration rate θ of an active material in an electrode plate of each battery cell;
plotting, by the control device, the estimated ion concentration rate θ of the each battery cell on a common θ-axis, any one of the battery cells serving as a reference battery cell, and a remaining one of the battery cells serving as a non-reference battery cell;
adjusting, by the control device, a length of the non-reference battery cell in accordance with a capacity of the non-reference battery cell based on a length of the reference battery cell that serves as a battery cell having a reference length value of 1;
shifting, by the control device, a position of the ion concentration rate θ of the non-reference battery cell on the θ-axis to agree with a position of the ion concentration rate θ of the reference battery cell on the θ-axis; and
estimating, by the control device, an SOC of the battery module using a range between the ion concentration rate θ at a lowest upper limit voltage of the battery cells and the ion concentration rate θ at a highest lower limit voltage of the battery cells as an SOC range of 100% to 0% of the battery module.

2. The method according to claim 1, wherein the estimating the ion concentration rate θ of the active material includes
calculating a cathode solid-phase potential difference and an anode solid potential difference in a thickness-wise direction of the each battery cell using a solid-phase diffusion model of the rechargeable battery,
expressing a difference between an average ion concentration of the active material and an ion concentration of an active material surface by a first-order lag model,
obtaining the ion concentration of the active material surface from the average ion concentration of the active material and an ion concentration flux of an average volume of the active material, and
estimating the ion concentration rate θ from the average ion concentration of the active material surface and a solid-phase maximum ion concentration.

3. The method according to claim 2, further comprising:
before the estimating the ion concentration rate θ of the active material, estimating, by the control device, a capacity of the electrode plate of the each battery cell; and
before the estimating the ion concentration rate θ of the active material, estimating, by the control device, a deterioration level of the each battery cell.

4. The method according to claim 1, further comprising:
after the estimating the SOC of the battery module, estimating, by the control device, the SOC based on only the ion concentration rate θ of the reference battery cell.

5. The method according to claim 1, further comprising:
after the estimating the SOC of the battery module, determining, by the control device, any of the battery cells to be anomalous if the any of the battery cells has a greater amount of change in the SOC, which is estimated based on the ion concentration rate θ, than other ones of the battery cells.

6. The method according to claim 1, further comprising:
before the estimating the SOC of the battery module, adjusting, by the control device, voltage of the battery cells by charging one of the battery cells having the lowest upper limit voltage or discharging one of the battery cells having the highest lower limit voltage.

7. The method according to claim 3, wherein the estimating the capacity of the electrode plate of the each battery cell includes:
executing, by a computer processor, an actual value acquisition process that generates an actual value SOC-voltage curve using a measurement result of an open-circuit voltage in the SOC range of 0% to 100% of the each battery cell;
executing, by the computer processor, a theoretical value generation process that generates, using a fitting function, a theoretical value SOC-voltage curve calculated from a difference between a cathode open-circuit potential theoretical curve, which is computed from a content of at least one component in a cathode composite of the each battery cell, and an anode open-circuit potential theoretical curve, which is computed from on a content of at least one component in an anode composite of the each battery cell;
executing, by the computer processor, an evaluation value calculation process that calculates an evaluation value using an evaluation function for calculating the evaluation value indicating a difference between the theoretical value SOC-voltage curve and the actual value SOC-voltage curve; and
executing, by the computer processor, an analysis process that repeatedly executes the theoretical value generation process and the evaluation value calculation process while changing a shift amount parameter, which is used in the fitting function to shift at least one of the cathode open-circuit potential theoretical curve and the anode open-circuit potential theoretical curve in an SOC direction, and a scaling rate parameter, which is used in the fitting function to adjust a length of at least one of the cathode open-circuit potential theoretical curve and the anode open-circuit potential theoretical curve in the SOC direction, and then outputs the shift amount parameter that minimizes the evaluation value as the deterioration level of the each battery cell.

8. The method according to claim 3, wherein the estimating the deterioration level of the each battery cell includes
calculating a side reaction current occurring in an anode of the each battery cell using a temperature of the each battery cell, and
calculating a deterioration index of the each battery cell based on the calculated side reaction current.

9. The method according to claim 1, wherein the electrode plate includes a cathode.

10. The method according to claim 1, wherein the rechargeable battery includes a lithium-ion rechargeable battery.

11. The method according to claim 1, wherein the length is a length of a line segment connecting the ion concentration ratio θ at the lowest upper limit voltage and the ion concentration ratio θ at the highest lower limit voltage plotted on the common θ-axis.
